(19) United States
(12) Patent Application Publication
(10) Pub. No.: US 2014/0014958 A1
(43) Pub. Date: Jan. 16, 2014

(54) SEMICONDUCTOR CHIP MODULE AND SEMICONDUCTOR PACKAGE HAVING THE SAME

(71) Applicant: SK HYNIX INC., Icheon-si Gyeonggi-do (KR)

(72) Inventors: Tac Keun OH, Seoul (KR); Jae Sung OH, Icheon-si Gyeonggi-do (KR); Kwon Whan HAN, Seoul (KR); Woong Sun LEE, Suwon-si Gyeonggi-do (KR); Seon Kwang JEON, Icheon-si Gyeonggi-do (KR)

(73) Assignee: SK HYNIX INC., Icheon-si Gyeonggi-do (KR)

(21) Appl. No.: 13/737,394

(22) Filed: Jan. 9, 2013

(30) Foreign Application Priority Data
Jul. 11, 2012 (KR) 10-2012-0075574

(51) Int. Cl. H01L 21/66

(52) U.S. Cl. CPC H01L 22/00
USPC 257/48

(57) ABSTRACT

A semiconductor chip module includes a first semiconductor chip having first through-electrodes, a second semiconductor chip having second through-electrodes which are electrically connected with the first through-electrodes, first and second test pads, a first connection line which connects the first test pad with one second through-electrode, a second connection line which connects the second test pad with another second through-electrode, third connection lines which connect the remaining second through-electrodes into pairs, and are partially constituted by fuses, and a third semiconductor chip having fourth connection lines which electrically connect the first through-electrodes of the first semiconductor chip into pairs, wherein the first and second is through-electrodes are connected in series between the first test pad and the second test pad by the first connection line, the second connection line, the third connection lines, and the fourth connection lines.

### CROSS-REFERENCE TO RELATED APPLICATIONS

The present application claims priority under 35 U.S.C 119(a) to Korean Patent Application Number 10-2012-75574 filed in the Korean Intellectual Property Office on Jul. 11, 2012, which is incorporated herein by reference in its entirety.

### BACKGROUND

1. Field of the Invention

The present invention relates generally to a semiconductor device, and in particular to a semiconductor chip module that has a structure suitable for testing a failure of a through-electrode, and a semiconductor package having the same.

2. Description of the Related Art

As electronic products are miniaturized, the sizes of packages used in the electronic products have grown smaller, and as various and complex application products are developed, packages capable of performing various functions have been demanded. Under this situation, a system-in-package, in which semiconductor chips with different functions, for example, a system chip, such as a CPU (central processing unit) and a GPU (graphic processing unit), and a memory chip are enclosed in one package to realize a system, is gaining in popularity.

As an example of the system-in-package, a product in which through-electrodes are formed in a memory chip and a system chip, and the memory chip and the system chip are directly connected using the through-electrodes, has been developed. In order to achieve a memory capacity larger than a memory capacity that can be realized through a semiconductor integration process, memory chips are not independently used, and instead, a memory chip module is manufactured by stacking a plurality of memory chips.

If a failure occurs in a through-electrode of the memory chip module, signal propagation becomes impossible, and both the memory chip module and the system chip become unusable. Thus, before connecting the memory chip module and the system chip, it is advisable to determine whether a failure has occurred in the through-electrodes of the memory chip module.

The most general test method is a method of individually testing the through-electrodes of the memory chip module using probes. However, because a large number of through-electrodes should be individually tested, a great deal of time and effort is needed. It is also very difficult to perform the probe test itself, when the size of the through-electrodes is too small to be readily compatible with probe testing.

### SUMMARY OF THE INVENTION

In an embodiment in accordance with the present invention, a semiconductor chip module comprises: a first semiconductor chip having a plurality of first through-electrodes; a second semiconductor chip stacked on one surface of the first semiconductor chip, and having a first surface which faces the first semiconductor chip, and a second surface which faces away from the first surface, and having second through-electrodes which pass through the first surface and the second surface and are electrically connected with the first through-electrodes; first and second test pads which are formed on the second surface; a first connection line which connects the first test pad with any one of the second through-electrodes; a second connection line which connects the second test pad with another one of the second through-electrodes; third connection lines which connect the second through-electrodes excluding the any one through-electrode and the another one through-electrode, into pairs, and are partially constituted by fuses; and a third semiconductor chip stacked on the other surface of the first semiconductor chip which faces away from the one surface, and having fourth connection lines which electrically connect the first through-electrodes of the first semiconductor chip, into pairs, wherein the first and second through-electrodes are connected in series between the first test pad and the second test pad by the first connection line, the second connection line, the third connection lines, and the fourth connection lines.

The third semiconductor chip may further have third through-electrodes which pass through one surface of the third semiconductor chip facing the first semiconductor chip and the other surface of the third semiconductor chip facing away from the one surface of the third semiconductor chip that are electrically connected with the first through-electrodes of the first semiconductor chip. The semiconductor chip module may further include an additional semiconductor chip stacked on the other surface of the third semiconductor chip that has a plurality of bonding pads which are electrically connected with the third through-electrodes.

The third connection lines may be formed on the inside of the second semiconductor chip, and the second semiconductor chip may further have openings which expose the fuses of the third connection lines, on the second surface.

The openings may be defined to individually expose the fuses. Alternatively, the openings may be defined such that each opening exposes at least two fuses.

The second semiconductor chip may be divided into a first region in which the second through-electrodes are disposed and a second region which is defined outside the first region, and the fuses may be disposed between the second through-electrodes in the first region. Alternatively, the fuses may be disposed in the second region.

In another embodiment of the present invention, a semiconductor package includes: a semiconductor chip module including a first semiconductor chip having a plurality of first through-electrodes; a second semiconductor chip stacked on one surface of the first semiconductor chip, and having a first surface which faces the first semiconductor chip and a second surface which faces away from the first surface, and having second through-electrodes which pass through the first surface and the second surface and are electrically connected with the first through-electrodes; first and second test pads which are formed on the second surface; a first connection line which connects the first test pad with any one of the second through-electrodes; a second connection line which connects the second test pad with another one of the second through-electrodes; and third connection lines which connect the second through-electrodes excluding the any one through-electrode and the another one through-electrode, into pairs, and are partially constituted by fuses; and a third semiconductor chip stacked on the other surface of the first semiconductor chip which faces away from the one surface, and having fourth connection lines which electrically connect the first through-electrodes of the first semiconductor chip, into pairs; and a fourth semiconductor chip stacked on the second surface of the second semiconductor chip and having fourth through-electrodes which are electrically connected with the second through-electrodes, respectively, of the second semiconductor chip, wherein the first through-electrodes and the second through-electrodes are connected in series between the first test pad and the second test pad by the first connection line, the second connection line, the third connection lines, and the fourth connection lines, and the fuses of the third connection lines are cut thereafter.

The fourth semiconductor chip may be a different type of chip compared with the first, second, and third semiconductor chips. For example, the first, second, and third semiconductor chips may be memory chips, and the fourth semiconductor chip may be a system chip.

The semiconductor package may further include a structural body supporting the semiconductor chip module and the fourth semiconductor chip, and having connection electrodes which are electrically connected with the fourth through-electrodes of the fourth semiconductor chip. The structural body may include any is one of a printed circuit board, an interposer, and a semiconductor package.

### DESCRIPTION OF THE DRAWINGS

The above and other features and advantages of the present invention will become readily apparent by reference to the following detailed description when considered in conjunction with the accompanying drawings wherein:

FIG. 1 is a cross-sectional view illustrating a semiconductor chip module in accordance with a first embodiment of the present invention.

FIG. 2 is a plan view of the second semiconductor chip shown in FIG. 1.

FIG. 3 is a plan view illustrating another embodiment of the second semiconductor chip shown in FIG. 1.

FIG. 4 is a cross-sectional view illustrating a semiconductor chip module in accordance with a second embodiment of the present invention.

FIG. 5 is a cross-sectional view illustrating a semiconductor package in accordance with a third embodiment of the present invention.

FIG. 6 is a perspective view illustrating an electronic apparatus including the semiconductor chip module according to the present invention.

FIG. 7 is a block diagram of an electronic system that is includes the semiconductor chip module according to the present invention.

### DETAILED DESCRIPTION

Hereafter, specific embodiments of the present invention will be described in detail with reference to the accompanying drawings. Although the present invention is described with reference to a number of example embodiments thereof, it should be understood that numerous variations and modifications can be devised by those skilled in the art that will fall within the spirit and scope of the invention.

It is to be understood herein that the drawings are not necessarily to scale and in some instances proportions may have been exaggerated in order to more clearly depict certain features of the invention.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of is describing particular embodiments only and is not intended to be limiting of the invention. As used herein, the singular forms “a,” “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

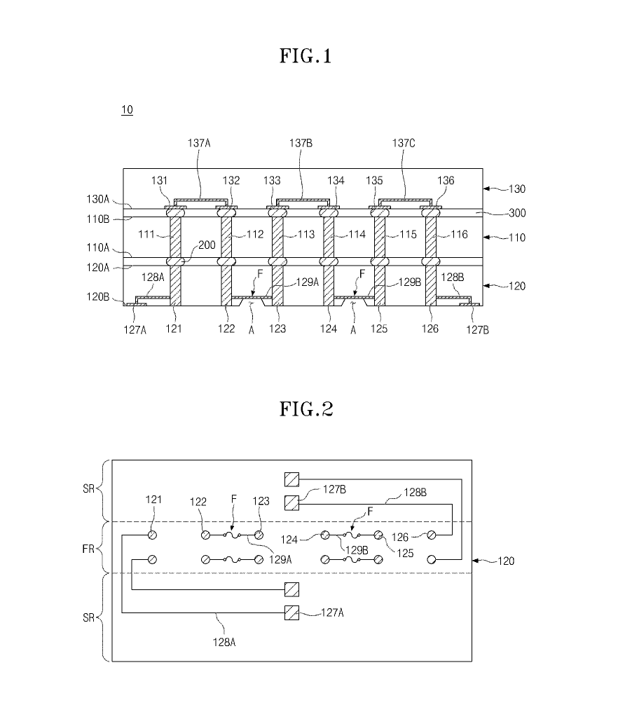

Referring to FIG. 1, a semiconductor chip module 10 in accordance with a first embodiment of the present invention includes first, second, and third semiconductor chips 110, 120, and 130. The semiconductor chip module 10 may also include conductive connection members 200 and adhesive members 300.

The first semiconductor chip 110 has one surface 110A, the other surface 1106, and a plurality of first through-electrodes 111, 112, 113, 114, 115, and 116. The one surface 110A faces away from the other surface 1106, and the respective first through-electrodes 111, 112, 113, 114, 115, and 116 pass through the one surface 110A and the other surface 1106.

Referring to FIGS. 1 and 2, the second semiconductor chip 120 is stacked on the one surface 110A of the first semiconductor chip 110. The second semiconductor chip 120 includes a plurality of second through-electrodes 121, 122, 123, 124, 125, and 126, first and second test pads 127A and 127B, first and second connection lines 128A and 128B, and third connection lines 129A and 129B.

The second semiconductor chip 120 has a first surface 120A which faces towards the first semiconductor chip 110 and a second surface 120B which faces away from the first surface 120A. The second through-electrodes 121, 122, 123, 124, 125, and 126 pass through the first surface 120A and the second surface 120B of the second semiconductor chip 120, and are electrically connected with the first through-electrodes 111, 112, 113, 114, 115, and 116, respectively, of the first semiconductor chip 110.

The first and second test pads 127A and 127B are formed on the second surface 120B of the second semiconductor chip 120. The first connection line 128A electrically connects the first test pad 127A with any one through-electrode of the second through-electrodes 121, 122, 123, 124, 125, and 126, such as through-electrode 121, and the second connection line 128B electrically connects the second test pad 127B and another one through-electrode of the second through-electrodes 121, 122, 123, 124, 125, and 126, such as through-electrode 126. The third connection lines 129A and 129B electrically connect the second through-electrodes 122, 123, 124 and 125 (excluding one through electrode 121 and another through electrode 126), into pairs. In FIG. 1, the third is connection line 129A electrically connects the second through electrode 122 with the second through electrode 123, and the third connection line 129B electrically connects the second through electrode 124 with the second through electrode 125. The first and second connection lines 128A and 128B, and the third connection lines 129A and 129B may be formed on the inside of the second semiconductor chip 120.

Referring back to FIG. 1, the third semiconductor chip 130 is stacked on the other surface 1106 of the first semiconductor chip 110. The third semiconductor chip 130 includes bonding pads 131, 132, 133, 134, 135, and 136, and fourth connection lines 137A, 137B, and 137C.

The bonding pads 131, 132, 133, 134, 135, and 136 are formed on one surface 130A of the third semiconductor chip 130 which faces the first semiconductor chip 110, and are electrically connected with the first through-electrodes 111, 112, 113, 114, 115, and 116, respectively, of the first semiconductor chip 110. The fourth connection lines 137A, 137B, and 137C electrically connect the bonding pads 131, 132, 133, 134, 135, and 136 into pairs. In FIG. 1, the fourth connection line 137A electrically connects the bonding pad 131 with the bonding pad 132, the fourth connection line 137B electrically connects the bonding pad 133 with the bonding pad 134, and the fourth connection line 137C electrically connects the bonding pad 135 with the bonding pad 136.

The first through-electrodes 111, 112, 113, 114, 115, and 116 of the first semiconductor chip 110 and the second through-electrodes 121, 122, 123, 124, 125, and 126 of the second semiconductor chip 120 are connected in series between the first test pad 127A and the second test pad 127B by the first connection line 128A, the second connection line 128B, the third connection lines 129A and 129B, and the fourth connection lines 137A, 137B, and 137C, and form a daisy chain.

The daisy chain is a term that is typically used to illustrate a computer structure, and describes a scheme in which all devices are connected in series based on a top priority. Herein, the daisy chain is used to broadly describe the through-electrodes connected in such a way as to follow one after another in a similar manner as the computer structure. The daisy chain refers to the first through-electrodes 111, 112, 113, 114, 115, and 116 of the first semiconductor chip 110 and the second through-electrodes 121, 122, 123, 124, 125, and 126 of the second semiconductor chip 120 connected in a zigzag manner between the first test pad 127A and the second test pad 127B through the first connection line 128A, the second connection line 128B, the third connection lines 129A and 129B, and the fourth connection lines 137A, 137B, and 137C.

Testing the through-electrodes of the semiconductor chip module 10 for failure includes applying an electrical signal to the first test pad 127A and checking whether the electrical signal is detected at the second test pad 127B. If the electrical signal is detected at the second test pad 127B, the semiconductor chip module 10 may meet standard requirements. Otherwise, the semiconductor chip module 10 may not meet standard requirements.

The third connection lines 129A and 129B are partially constituted by fuses F. The fuses F of the third connection lines 129A and 129B are cut through laser cutting or electrical cutting after the test is completed, so as to avoid interference with a normal operation.

In the present embodiment, the second semiconductor chip 120 has openings A which expose the fuses F, on the second surface 120B. After the testing of the through-electrodes for failure is complete, the fuses F of the semiconductor chip module 10 that are considered to meet standard requirements are cut along the openings A by a laser.

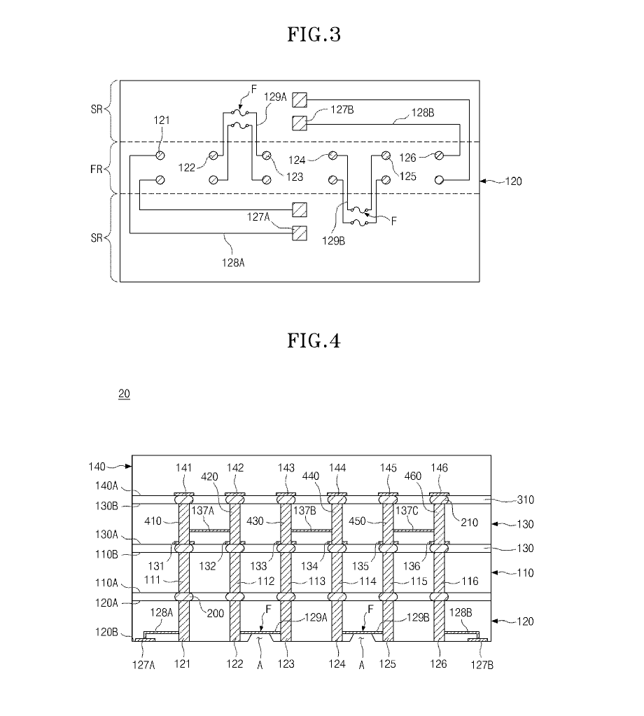

Referring to FIG. 2, the second semiconductor chip 120 is divided into a first region FR in which the second through-electrodes 121, 122, 123, 124, 125, and 126 are disposed and a second region SR which is defined outside the first region FR. The fuses F are disposed between the second through-electrodes 121, 122, 123, 124, 125, and 126 in the first region FR. Alternatively, as shown in FIG. 3, the fuses F may be disposed in the second region SR.

Referring back to FIG. 1, the openings A are defined to individually expose the fuses F.

Although not shown, the openings A may alternatively be defined in such a manner that each opening A exposes at least two fuses F at once. Since it is possible to simultaneously cut a plurality of fuses F, cutting at least two fuses F at once may prove to be advantages and may be easily performed.

When cutting the fuses F by electrical cutting rather than by laser cutting, openings A may not need to be defined.

The first, second, and third semiconductor chips 110, 120, and 130 may be substantially similar chips, such as memory chips.

The conductive connection members 200 are formed between the first through-electrodes 111, 112, 113, 114, 115, and 116 of the first semiconductor chip 110 and the second through-electrodes 121, 122, 123, 124, 125, and 126 of the second semiconductor chip 120, and also formed between the first through-electrodes 111, 112, 113, 114, 115, and 116 of the first semiconductor chip 110 and the bonding pads 131, 132, 133, 134, 135, and 136 of the third semiconductor chip 130. The conductive connection members 200 also electrically connect the first through-electrodes 111, 112, 113, 114, 115, and 116 with the second through-electrodes 121, 122, 123, 124, 125, and 126, and also electrically connect the first through-electrodes 111, 112, 113, 114, 115, and 116 with the bonding pads 131, 132, 133, 134, 135, and 136.

The adhesive members 300 are formed between the first, second, and third semiconductor chips 110, 120, and 130 and attach upper and lower semiconductor chips to each other.

The conductive connection members 200 may be formed of a metal which contains at least one of copper, tin, and silver. The adhesive members 300 may include any one of a non-conductive film (NCF), a non-conductive paste (NCP), an anisotropic conductive film (ACF), an anisotropic conductive paste (ACP), and a polymer.

Unlike the first embodiment described above with reference to FIG. 1, the semiconductor chip module 20 in accordance with the second embodiment of the present invention has a construction where third through-electrodes 410, 420, 430, 440, 450, and 460 are added in a third semiconductor chip 130 and an additional semiconductor chip 140 is further stacked on the third semiconductor chip 130. Accordingly, the semiconductor chip module in accordance with the second embodiment of the present invention has a substantially similar construction as the semiconductor chip module in accordance with the first embodiment of the present invention except for the added components including the third through-electrodes 410, 420, 430, 440, 450, and 460 and the additional semiconductor chip 140. Therefore, repeated descriptions for the same component parts will be omitted herein, and same terms and reference numerals will be used to refer to substantially similar component parts.

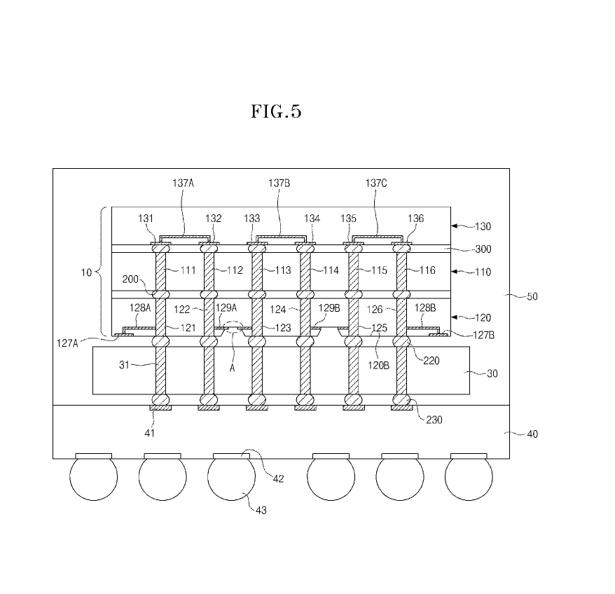

In FIG. 4, the third semiconductor chip 130 contains the third through-electrodes 410, 420, 430, 440, 450, and 460. The third through-electrodes 410, 420, 430, 440, 450, and 460 pass through one surface 130A of the third semiconductor chip 130 which faces the first semiconductor chip 110 and the other surface of the third semiconductor chip 130 which faces away from the one surface 130A, and are electrically connected with bonding pads 131, 132, 133, 134, 135, and 136, respectively. The additional semiconductor chip 140 is stacked on the other surface 130B of the third semiconductor chip 130.

The additional semiconductor chip 140 contains bonding pads 141, 142, 143, 144, 145, and 146 which are electrically connected with the third through-electrodes 410, 420, 430, 440, 450, and 460 of the third semiconductor chip 130, on one surface 140A which faces the third semiconductor chip 130.

The additional semiconductor chip 140 may be a substantially similar kind of chip as the first, second, and third semiconductor chips 110, 120 and 130, such as memory chips.

The third through-electrodes 410, 420, 430, 440, 450, and 460 of the third semiconductor chip 130 and the bonding pads 141, 142, 143, 144, 145, and 146 of the additional semiconductor chip 140 are electrically connected with each other by conductive connection members 210, and the third semiconductor chip 130 and the additional semiconductor chip 140 are attached to each other by is an adhesive member 310.

In FIG. 5, after the semiconductor chip 10 shown in FIG. 1 is formed, testing through-electrodes for failure is performed by inspecting whether the first test pad 127A and the second test pad 127B are electrically connected with each other. Further, in order to avoid interference with a normal operation, the fuses F formed in the semiconductor chip module 10 that meet standard requirements as a result of the test are cut. In FIG. 5, a place where a fuse is cut is depicted by A.

A fourth semiconductor chip 30 is mounted to a second surface 120B of a second semiconductor chip 120 in such a manner that fourth through-electrodes 31 of the fourth semiconductor chip 30 are electrically connected with second through-electrodes 121, 122, 123, 124, 125, and 126, respectively, of a second semiconductor chip 120.

The fourth semiconductor chip 30 may be a different type of chip compared with first, second, and third semiconductor chips 110, 120, and 130 included in the semiconductor chip module 10. For example, the first, second, and third semiconductor chips 110, 120, and 130 may be memory chips, and the fourth semiconductor chip 30 may be a system chip.

The fourth semiconductor chip 30 is mounted to a structural body 40 such that the fourth through-electrodes 31 of the fourth semiconductor chip 30 are electrically connected with is connection electrodes 41 of the structural body 40. The structural body 40 may be constituted by a printed circuit board (PCB).

The second through-electrodes 121, 122, 123, 124, 125, and 126 of the second semiconductor chip 120 and the fourth through-electrodes 31 of the fourth semiconductor chip 30 are electrically connected with each other by conductive connection members 220, and the fourth through-electrodes 31 of the fourth semiconductor chip 30 and the connection electrodes 41 of the structural body 40 are electrically connected with each other by conductive connection members 230. The reference numeral 42 designates ball lands, 43 designates solder balls used as external connection terminals, and 50 designates a mold part which seals the upper surface of the structural body 40 including the semiconductor chip module 10 and the fourth semiconductor chip 30.

Although it was described in the embodiment shown in FIG. 5 that the structural body 40 may be constituted by a printed circuit board (PCB), it is to be noted that the structural body 40 may be constituted by a semiconductor package or an interposer.

Although it was described in an embodiment shown in FIG. 5 that the package may be manufactured using the semiconductor chip module 10 shown in FIG. 1, a person skilled in the art will readily appreciate that the package may be manufactured using the semiconductor chip module 20 shown in FIG. 4 instead of the semiconductor chip module 10 shown in FIG. 1. Thus, a detailed description thereof will be omitted herein.

The semiconductor chip modules described above may be applied to various electronic apparatuses.

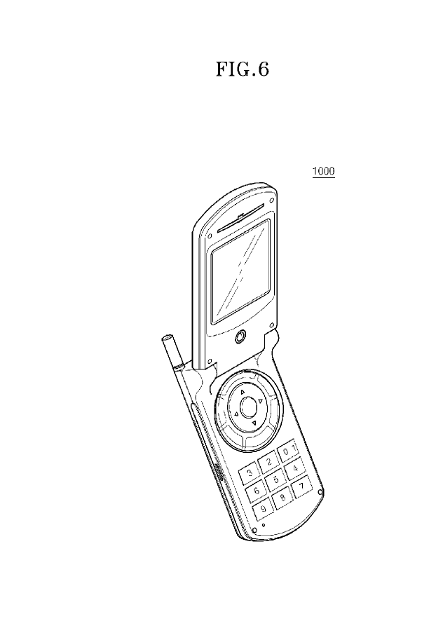

In FIG. 6, the semiconductor chip module according to embodiments of the present invention may be applied to an electronic apparatus 1000 such as a portable phone. The electronic apparatus 1000 is not limited to the portable phone shown in FIG. 6, and may include various electronic appliances such as a mobile electronic appliance, a laptop computer, a notebook computer, a portable multimedia player (PMP), an MP3 player, a camcorder, a web tablet, a wireless phone, a navigator, a personal digital assistant (PDA), and so forth.

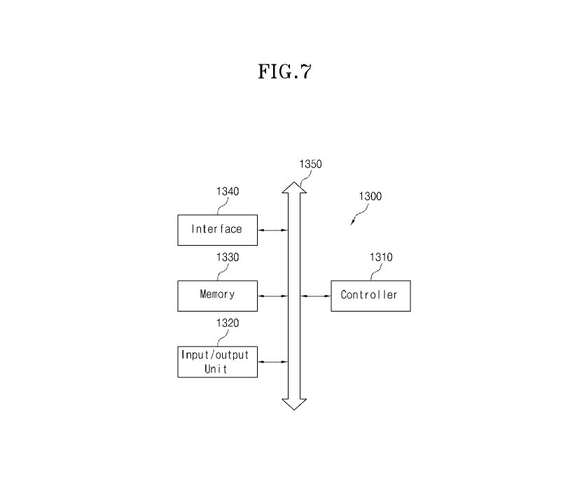

In FIG. 7, an electronic system 1300 may include a controller 1310, an input/output unit 1320, and a memory 1330 that collectively may be coupled with one another through a bus 1350. The bus 1350 serves as a path through which data move. The controller 1310 may include at least one microprocessor, one digital signal processor, one microcontroller, and logic devices capable of performing substantially similar functions as these components. The controller 1310 and the memory 1330 may include the semiconductor chip module according to the present invention. The input/output unit 1320 may include at least one keypad, a keyboard, a display device, and so forth. The memory 1330 is a device for storing data, and may store data and/or commands to be executed by the controller 1310, and the likes. The memory 1330 may include a volatile memory device and/or a nonvolatile memory device. Otherwise, the memory 1330 may be constituted by a flash memory, where the flash memory to which the technology of the present invention is applied may be mounted to an information processing system such as a mobile terminal or a desktop computer. The flash memory may be constituted by a solid state drive (SSD). The electronic system 1300 may stably store a large amount of data in a flash memory system, and may further include an interface 1340 configured to transmit and receive data to and from a communication network. The interface 1340 may be a wired or wireless type. The interface 1340 may include an antenna or a wired or wireless transceiver. Further, while not shown, a person skilled in the art will readily appreciate that the electronic system 1300 may be additionally utilize an application chipset, a camera image processor (CIS), an input/output unit, etc.

As is apparent from the above description, according to embodiments of the present invention, since through-electrodes of semiconductor chips constituting a semiconductor chip module are connected in series, failure in the through-electrodes of the semiconductor chip module may be tested easily and quickly within a short time. Also, because tests may be performed even when the size of through-electrodes is too small for a probe test, it is possible is to prevent a semiconductor chip module with a failed through-electrode from being shipped to market, thereby improving reliability of a product.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor chip module comprising:
a first semiconductor chip having a plurality of first through-electrodes;
a second semiconductor chip stacked on one surface of the first semiconductor chip, and having a first surface which faces the first semiconductor chip, and a second surface which faces away from the first surface, and having second through-electrodes which pass through the first surface and the second surface and are electrically connected with the first through-electrodes;
first and second test pads which are formed on the second surface;
a first connection line which connects the first test pad with is any one of the second through-electrodes;
a second connection line which connects the second test pad with another one of the second through-electrodes;
third connection lines which connect the second through-electrodes excluding the any one through-electrode and the another one through-electrode, into pairs, and are partially constituted by fuses; and
a third semiconductor chip stacked on the other surface of the first semiconductor chip which faces away from the one surface, and having fourth connection lines which electrically connect the first through-electrodes of the first semiconductor chip, into pairs,
wherein the first and second through-electrodes are connected in series between the first test pad and the second test pad by the first connection line, the second connection line, the third connection lines, and the fourth connection lines.

2. The semiconductor chip module according to claim 1, wherein the third semiconductor chip further has third through-electrodes which pass through one surface of the third semiconductor chip facing the first semiconductor chip and the other surface of the third semiconductor chip facing away from the one surface that are electrically connected with the first through-electrodes of the first semiconductor chip.

3. The semiconductor chip module according to claim 2, further comprising:
an additional semiconductor chip stacked on the other surface of the third semiconductor chip that has a plurality of bonding pads which are electrically connected with the third through-electrodes, respectively.

4. The semiconductor chip module according to claim 1, wherein the third connection lines may be formed on the inside of the second semiconductor chip, and the second semiconductor chip further has openings which expose the fuses of the third connection lines, on the second surface.

5. The semiconductor chip module according to claim 4, wherein the openings are defined to individually expose the fuses.

6. The semiconductor chip module according to claim 4, wherein the openings are defined such that each opening exposes at least two fuses.

7. The semiconductor chip module according to claim 1,
wherein the second semiconductor chip is divided into a first region in which the second through-electrodes are disposed and a second region which is defined outside the first region, and
wherein the fuses are disposed between the second through-electrodes in the first region.

8. The semiconductor chip module according to claim 1,
wherein the second semiconductor chip is divided into a first region in which the second through-electrodes are disposed and a second region which is defined outside the first region, and
wherein the fuses are disposed in the second region.

9. A semiconductor package comprising:
a semiconductor chip module including,
a first semiconductor chip having a plurality of first through-electrodes;
a second semiconductor chip stacked on one surface of the first semiconductor chip, and having a first surface which faces the first semiconductor chip and a second surface which faces away from the first surface, and having second through-electrodes which pass through the first surface and the second surface and are electrically connected with the first through-electrodes;
first and second test pads which are formed on the second surface;
a first connection line which connects the first test pad with any one of the second through-electrodes;
a second connection line which connects the second test pad with another one of the second through-electrodes;
third connection lines which connect the second through-electrodes excluding the any one through-electrode and the another one through-electrode, into pairs, and are partially constituted by fuses;
a third semiconductor chip stacked on the other surface of the first semiconductor chip which faces away from the is one surface; and
fourth connection lines which electrically connect the first through-electrodes of the first semiconductor chip, into pairs, and
a fourth semiconductor chip stacked on the second surface of the second semiconductor chip and having fourth through-electrodes which are electrically connected with the second through-electrodes, respectively, of the second semiconductor chip,
wherein the first through-electrodes and the second through-electrodes are connected in series between the first test pad and the second test pad by the first connection line, the second connection line, the third connection lines, and the fourth connection lines, and the fuses of the third connection lines are cut thereafter.

10. The semiconductor package according to claim 9, wherein the third semiconductor chip further has third through-electrodes which pass through one surface of the third semiconductor chip facing the first semiconductor chip and the other surface of the third semiconductor chip facing away from the one surface that are electrically connected with the first through-electrodes of the first semiconductor chip.

11. The semiconductor package according to claim 10, wherein the semiconductor chip module further includes an additional semiconductor chip stacked on the other surface of the third semiconductor chip that has a plurality of bonding pads which are electrically connected with the third through-electrodes, respectively.

12. The semiconductor package according to claim 9, wherein the third connection lines may be formed on the inside of the second semiconductor chip, and the second semiconductor chip further has openings which expose the fuses of the third connection lines, on the second surface.

13. The semiconductor package according to claim 12, wherein the openings are defined to individually expose the fuses.

14. The semiconductor package according to claim 12, wherein the openings are defined such that each opening exposes at least two fuses.

15. The semiconductor package according to claim 9,
wherein the second semiconductor chip is divided into a first region in which the second through-electrodes are disposed and a second region which is defined outside the first region, and
wherein the fuses are disposed between the second through-electrodes in the first region.

16. The semiconductor package according to claim 9,
wherein the second semiconductor chip is divided into a first region in which the second through-electrodes are disposed and a second region which is defined outside the first region, and
wherein the fuses are disposed in the second region.

17. The semiconductor package according to claim 9, wherein the fourth semiconductor chip is a different type of chip compared with the first, second, and third semiconductor chips.

18. The semiconductor package according to claim 17, wherein the first, second, and third semiconductor chips are memory chips, and the fourth semiconductor chip is a system chip.

19. The semiconductor package according to claim 9, further comprising:
a structural body supporting the semiconductor chip module and the fourth semiconductor chip, and having connection electrodes which are electrically connected with the fourth through-electrodes of the fourth semiconductor chip.

20. The semiconductor package according to claim 19, wherein the structural body comprises any one of a printed circuit board, an interposer, and a semiconductor package.
